(19) United States
(12) Patent Application Publication
(10) Pub. No.: US 2011/0049563 A1
(43) Pub. Date: Mar. 3, 2011

(54) MOS GATE POWER SEMICONDUCTOR DEVICE

(76) Inventors: Kwang-Hoon Oh, Seoul (KR); Byoung-Ho Choo, Bucheon-si (KR); Soo-Seong Kim, Seoul (KR); Chong-Man Yun, Seoul (KR)

(21) Appl. No.: 12/699,662

(22) Filed: Feb. 3, 2010

(30) Foreign Application Priority Data
Sep. 3, 2009 (KR) 10-2009-0082820

(51) Int. Cl. H01L 27/06

(52) U.S. Cl. 257/140; 257/E27.017

(57) ABSTRACT

A MOS-gate power semiconductor device is provided which includes: one or more P-type wells formed under one or more of a gate metal electrode and a gate bus line and electrically connected to an emitter metal electrode; and one or more N-type wells formed in the P-type well and electrically connected to one or more of the gate metal electrode and the gate bus line. According to this configuration, it is possible to suppress deterioration and/or destruction of a device due to an overcurrent.

### BACKGROUND

1. Technical Field

The present invention relates to a semiconductor device, and more particularly, to a MOS-gate power semiconductor device.

2. Description of the Related Art

Semiconductor devices such as an insulated gate bipolar transistor (IGBT) and a metal-oxide semiconductor field effect transistor (MOSFET) are mainly used as switching devices in the field of power electronic applications. That is, the semiconductor devices are used as semiconductor switching devices in the power electronic applications such as an H-bridge inverter, a half-bridge inverter, a 3-phase inverter, a multi-level inverter, and a converter.

However, in power electronic circuits including the semiconductor switching devices (that is, semiconductor devices used as the semiconductor switching devices), the semiconductor switching devices may happen to be deteriorated or destructed by the overcurrent flow due to a malfunction of driving circuitry. Accordingly, it is necessary to avoid such failures due to the overcurrent and moreover to prevent the deterioration and/or destruction of the semiconductor switching devices.

Hereinafter, operations of an H-bridge inverter circuit employing the semiconductor switching devices will be described along with a shoot-through phenomenon as an example of the failure in the circuit.

FIGS. 1A and 1B are a circuit diagram illustrating the H-bridge inverter circuit employing the IGBT and a graph illustrating its gate voltage and load voltage characteristics, respectively.

As shown in FIG. 1A, the H-bridge inverter circuit includes four semiconductor switching devices M1 to M4 and a load 120 connected to an output node 110 between the semiconductor switching devices. The IGBTs are shown as the semiconductor switching devices in FIG. 1A, but semiconductor switching devices such as MOSFETs may be also employed.

The semiconductor switching devices M1 to M4 included in the H-bridge inverter circuit are alternately turned on and off in a switching sequence to supply AC power to the load 120 connected to the output node 110 between the semiconductor switching devices. Here, each pair of semiconductor switching devices is called arm or leg.

When the semiconductor switching devices M1 and M3 are turned on and the semiconductor switching devices M2 and M4 are turned off under the control of a driving circuit for the semiconductor switching devices, a current flows in the direction of A. On the contrary, when the semiconductor switching devices M2 and M4 are turned on and the semiconductor switching devices M1 and M3 are turned off, the current flows in the direction of B.

Accordingly, as shown in FIG. 1B, when the semiconductor switching devices M1 and M3 are maintained in the ON state for a half of a switching period T and the semiconductor switching devices M2 and M4 are maintained in the ON state for the other half of the switching period T, the output voltage to the load 120 has a shape of AC voltage of which the polarity varies. In this way, when the turning-on/off operations of the semiconductor switching devices are normally controlled by the driving circuit, the current in the direction of A or B flows into the load.

Therefore, it is indispensible to control the semiconductor switching devices M1 and M4 (or M2 and M3) disposed in the same arm not to simultaneously be in the ON state. As shown in FIG. 1B, the semiconductor switching devices are controlled to have a dead time between the turning-off of M1 and the turning-on of M4 or between the turning-off of M4 and the turning-on of M1 (which is true in M2 and M3).

Otherwise, a short circuit is formed between the semiconductor switching devices disposed in the same arm to cause the shoot-through phenomenon, when the semiconductor switching devices disposed in the same arm are simultaneously in the ON state. That is, a very large short circuit current flows through the formed short circuit, which causes the deterioration and/or destruction of the semiconductor switching devices.

FIG. 2 is a plan view illustrating a known semiconductor switching device and FIG. 3 is a sectional view taken along line a-b of FIG. 2.

Referring to FIGS. 2 and 3, a semiconductor substrate 200 formed of silicon has a top surface and a bottom surface opposed to each other. A gate pad electrode 210, an active area 220 including plural cells allowing a current to flow, and an edge termination area 230 supporting a high withstand voltage are formed in the top surface. A collector metal electrode 310 is formed in the bottom surface. Unit cells including a gate poly electrode and an emitter metal electrode are arranged in the active area 220. A gate bus line 240 electrically connected to a gate pad to transmit a gate signal extends around the active area 220 from the gate pad electrode 210. For example, the gate bus line 240 can be formed in a closed loop, but the pattern is not limited to the closed loop.

Referring to FIG. 3 showing a sectional view taken along line a-b of FIG. 2, plural P-type wells 320 and 322 are formed in an N-type semiconductor substrate 315 and N-type wells 325 are selectively formed in the P-type wells 322. The P-type well 322 forms an active cell allowing a current to flow at the time of turning on the semiconductor device, along with a gate oxide film 330 and a gate poly electrode 335. A channel can be formed in the P-type well 322, allowing a current to flow by connecting the semiconductor substrate 315 to the N-type well 325, when a gate voltage having a predetermined level is applied to a gate metal electrode 210. An insulating interlayer 340 is formed to include the gate poly electrode 335 therein and an emitter metal electrode 345 including active cells is formed thereon. A collector region 350 is formed under the N-type semiconductor substrate 315 and a collector metal electrode 310 is formed under the collector region 350 by a bottom metal process. The collector region 350 is formed in a P type in case of the IGBT, and is formed in an N type as a drain region in case of the MOSFET.

When the semiconductor device shown in FIG. 3 is the semiconductor switching device M1 shown in FIG. 1A, the collector metal electrode 310 is connected to a + terminal of an input voltage and the emitter metal electrode 345 is electrically connected to the output node 110. Accordingly, when the semiconductor switching device is in the ON state, the current flows to the output node 110.

In an abnormal state such as the above-mentioned shoot-through phenomenon, an overcurrent flows to the outside via the emitter metal electrode 345, which can cause the deterioration and/or destruction of the semiconductor switching device.

To prevent the shoot-through phenomenon, the semiconductor devices are controlled with the dead time. However, the possibility that the shoot-through phenomenon occurs cannot be completely excluded in various abnormal states where the control sequence of the driving circuit is not normally designed or the driving circuit for the semiconductor switching devices operates erroneously.

Particularly, since a tail current exists due to the characteristic of the IGBT, a sufficient dead time is required for preventing the shoot-through phenomenon. However, the elongation of the dead time causes an increase in harmonics due to the distortion in output waveform of an inverter, thereby lowering the performance of the inverter.

Therefore, there is a need for preventing the deterioration and/or destruction of a semiconductor switching device by switching or maintaining its operating state to or in the OFF state in an abnormal state such as the shoot-through phenomenon, and suppressing a failure from occurring in the driving circuit.

The above-mentioned background art is technical information thought out to make the invention or learned in the course of making the invention by the inventor, and cannot be thus said to be technical information known to the public before filing the invention.

### SUMMARY

An advantage of some aspects of the invention is that it provides a MOS-gate power semiconductor device which can prevent deterioration and/or destruction of a semiconductor switching device by switching or maintaining its operating state to or in the OFF state in an abnormal state such as a shoot-through phenomenon and suppress a failure from occurring in a driving circuit.

Another advantage of some aspects of the invention is that it provides a MOS-gate power semiconductor device which can fundamentally suppress a shoot-through phenomenon from occurring in an inverter circuit or the like.

Another advantage of some aspects of the invention is that it provides a MOS-gate power semiconductor device which can allow a decrease in weight, thickness, and size of a power electronic circuit by building a self protecting function in the semiconductor switching device without being embodied in combination with a particular diode.

Other advantages of the invention will be easily understood from the following description.

According to an aspect of the invention, there is provided a MOS-gate power semiconductor device including: one or more P-type wells formed under one or more of a gate metal electrode and a gate bus line and electrically connected to an emitter metal electrode; and one or more N-type wells formed in the P-type well and electrically connected to one or more of the gate metal electrode and the gate bus line.

The P-type wells may serve as an anode of a diode and the N-type wells may serve as a cathode of the diode.

The P-type wells and the N-type wells may be formed by performing an ion implantation process and a diffusion process on a semiconductor substrate.

In the MOS-gate power semiconductor device, a plurality of diodes formed using P-type ions of the P-type wells and N-type ions of the N-type wells may be arranged in one or more of a serial connection and a parallel connection between a gate terminal and an emitter terminal.

The MOS-gate power semiconductor device may serve as one or more of an insulated gate bipolar transistor (IGBT) and a metal-oxide semiconductor field effect transistor (MOSFET).

According to another aspect of the invention, there is provided a MOS-gate power semiconductor device including: one or more P-type wells formed in a semiconductor substrate so as to electrically be connected to an anode metal pad exposed from a surface of the MOS-gate power semiconductor device; and one or more N-type wells formed in the semiconductor substrate so as to electrically be connected to a cathode metal pad exposed from the surface.

The anode metal pad may be electrically connected to an emitter metal electrode and the cathode metal pad may be electrically connected to one or more of a gate metal electrode and a gate bus line.

The P-type wells and the N-type wells may be formed by performing an ion implantation process and a diffusion process on the semiconductor substrate.

The N-type wells may be formed in the P-type wells so as to serve as a PN-junction diode.

The P-type wells and the N-type wells may be formed in an area other than an edge termination area.

In the MOS-gate power semiconductor device, the anode metal pad and the cathode metal pad may be formed in an active area so as to be exposed from the active area.

In the MOS-gate power semiconductor device, a plurality of diodes are arranged in one or more of a serial connection and a parallel connection between a gate metal terminal and an emitter metal terminal by wiring the anode metal pad and the cathode metal pad.

The MOS-gate power semiconductor device may serve as one or more of an insulated gate bipolar transistor (IGBT) and a metal-oxide semiconductor field effect transistor (MOSFET).

According to the aspects of the invention, it is possible to prevent deterioration and/or destruction of a semiconductor switching device by switching or maintaining its operating state to or in the OFF state in an abnormal state such as a shoot-through phenomenon and to suppress a failure from occurring in a driving circuit.

It is also possible to fundamentally suppress a shoot-through phenomenon from occurring in an inverter circuit or the like.

It is also possible to allow a decrease in weight, thickness, and size of power electronic circuit by building a self protecting function in the semiconductor switching device without being embodied in combination with a particular diode.

### BRIEF DESCRIPTION OF THE DRAWINGS

FIGS. 1A and 1B are a circuit diagram illustrating a H-bridge inverter circuit employing a known IGBT and a graph illustrating its gate voltage and load voltage characteristics.

FIG. 2 is a plan view illustrating a known semiconductor switching device.

FIG. 3 is a sectional view taken along line a-b of FIG. 2.

FIG. 4 is a circuit diagram illustrating an arm of an inverter circuit according to an embodiment of the invention.

FIG. 5 is a sectional view taken along line a-b of FIG. 2 according to an embodiment of the invention.

FIG. 6 is a conceptual plan view illustrating a semiconductor device according to an embodiment of the invention.

FIG. 7 is a plan view illustrating a semiconductor device according to another embodiment of the invention.

### DESCRIPTION OF EXEMPLARY EMBODIMENTS

The invention can be variously modified in various forms and specific embodiments will be described and shown in the drawings. However, the embodiments are not intended to limit the invention, but it should be understood that the invention includes all the modifications, equivalents, and replacements belonging to the spirit and the technical scope of the invention. When it is determined that detailed description of known techniques associated with the invention makes the gist of the invention obscure, the detailed description will be omitted.

Terms such as “first” and “second” can be used to describe various elements, but the elements are not limited to the terms. The terms are used only to distinguish one element from another element.

The terms used in the following description are used to merely describe specific embodiments, but are not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

If it is mentioned that an element such as a layer, a region, and a substrate is disposed “on” another element or extends “onto” another element, it should be understood that the element is disposed directly on another element or extends directly onto another element, or still another element is interposed therebetween. On the contrary, if it is mentioned that an element is disposed “directly on” another element or extends “directly onto” another element, it should be understood that still another element is not interposed therebetween. If it is mentioned that an element is “connected to” or “coupled to” another element, it should be understood that still another element may be interposed therebetween, as well as that the element may be connected or coupled directly to another element. On the contrary, if it is mentioned that an element is “connected directly to” or “coupled directly to” another element, it should be understood that still another element is not interposed therebetween.

Relative terms such as “below”, “above”, “upper”, “lower”, “horizontal”, “lateral”, and “vertical” can be used to describe the relative relation of an element, layer, or region to another element, layer, or region as shown in the drawings. The terms are intended to include another direction of a device relative to an orientation shown in the drawings.

The exemplary embodiments of the invention will be described now in detail with reference to the accompanying drawings. Although an IGBT used as a semiconductor switching device in an H-bridge inverter circuit will be mainly described, a semiconductor switching device with the same technical spirit can be applied to various power electronics fields such as a half-bridge inverter, a 3-phase inverter, a multi-level inverter, and a converter without any particular restriction.

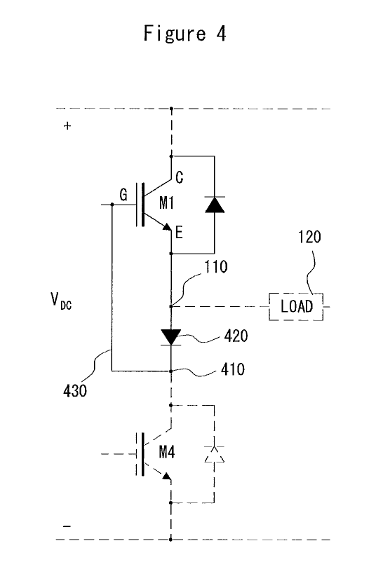

FIG. 4 is a circuit diagram illustrating an arm of an inverter according to an embodiment of the invention.

As shown in FIG. 4, the arm of an inverter includes an upper semiconductor switching device M1 and a lower semiconductor switching device M4 connected in series to cross a power supply line. As shown in the drawing, the semiconductor switching devices are IGBT, but may be replaced with a power MOSFET.

An output node 110 supplying current to a load 120 is disposed between the upper semiconductor switching device M1 and the lower semiconductor switching device M4.

A diode 420 is interposed between the output node 110 and a connection node 410. The connection node 410 is connected to the gate terminal of the upper semiconductor switching device M1 via a conductive line 430. Accordingly, the diode 420 is disposed between the emitter terminal and the gate terminal of the upper semiconductor switching device M1 and between the emitter terminal of the upper semiconductor switching device M1 and the collector terminal of the lower semiconductor switching device M4. When the upper semiconductor switching device M1 and the lower semiconductor switching device M4 is a power MOSFET, the diode 420 is disposed between the source terminal and the gate terminal of the upper semiconductor switching device M1 and between the source terminal of the upper semiconductor switching device M1 and the drain terminal of the lower semiconductor switching device M4.

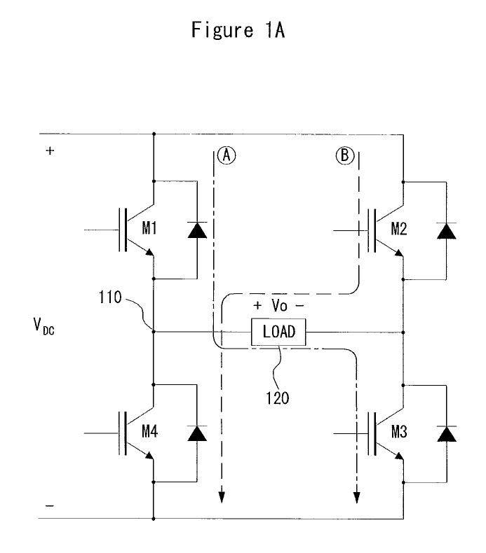

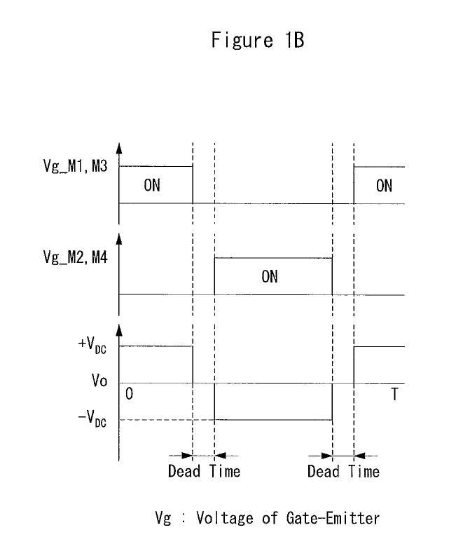

The diode 420 serves to turn off the upper semiconductor switching device M1 or to maintain the upper semiconductor switching device M1 in the OFF state, when a current is input to the lower semiconductor switching device M4. As described with reference to FIGS. 1A and 1B, the upper semiconductor switching device M1 is maintained in the OFF state when the current flows in the direction of B, and the upper semiconductor switching device M1 is switched to the OFF state when the shoot-through phenomenon occurs. Accordingly, it is possible to prevent the shoot-through phenomenon from occurring and thus to prevent the deterioration and/or destruction of the semiconductor switching devices M1 and M4 due to the overcurrent resulting from the shoot-through phenomenon

For example, in an abnormal state of the circuit where two semiconductor switching devices disposed in one arm are simultaneously turned on, the gate potential of the upper semiconductor switching device M1 is lower than the emitter potential due to the voltage drop (about 0.7 V) due to the turning-on of the diode 420. Accordingly, the gate potential of the upper semiconductor switching device M1 is not maintained to be equal to or greater than a threshold voltage and the upper semiconductor switching device M1 is forcibly turned off, thereby preventing the shoot-through phenomenon.

It is preferable that the breakdown voltage of the diode is set to be equal to or greater than the gate oxide breakdown voltage of the semiconductor switching device and the forward voltage drop at the time of turning on the diode is small.

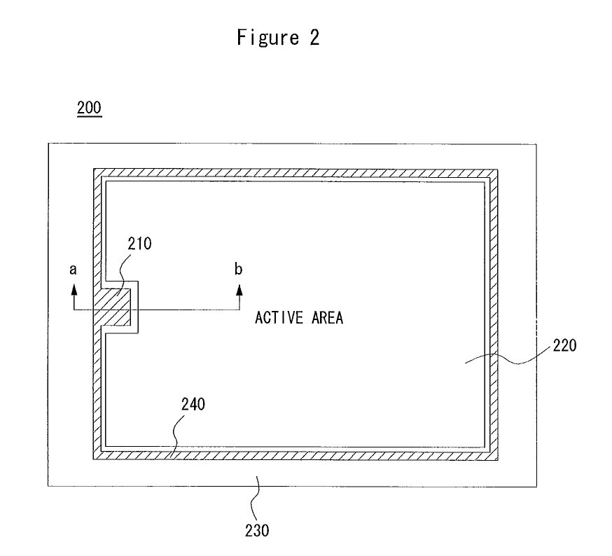

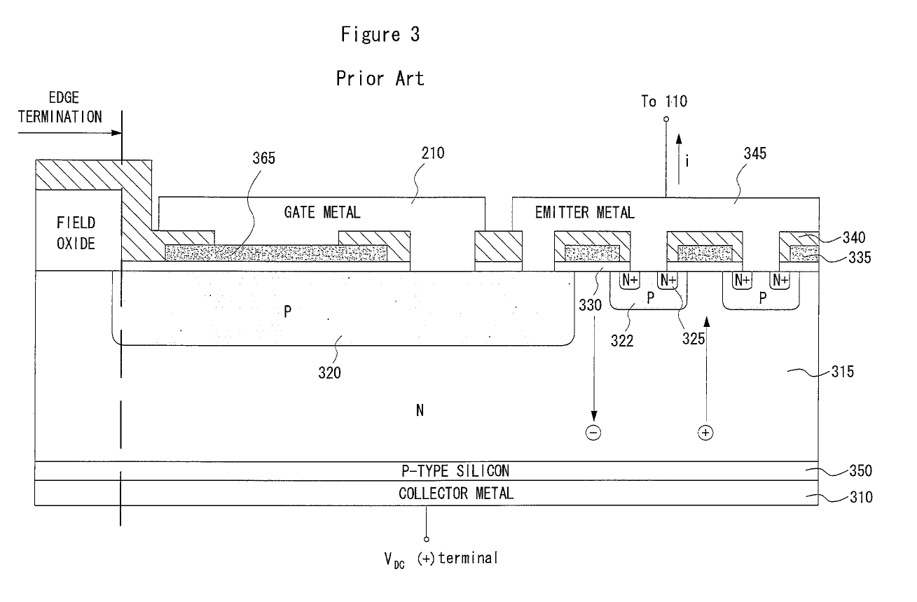

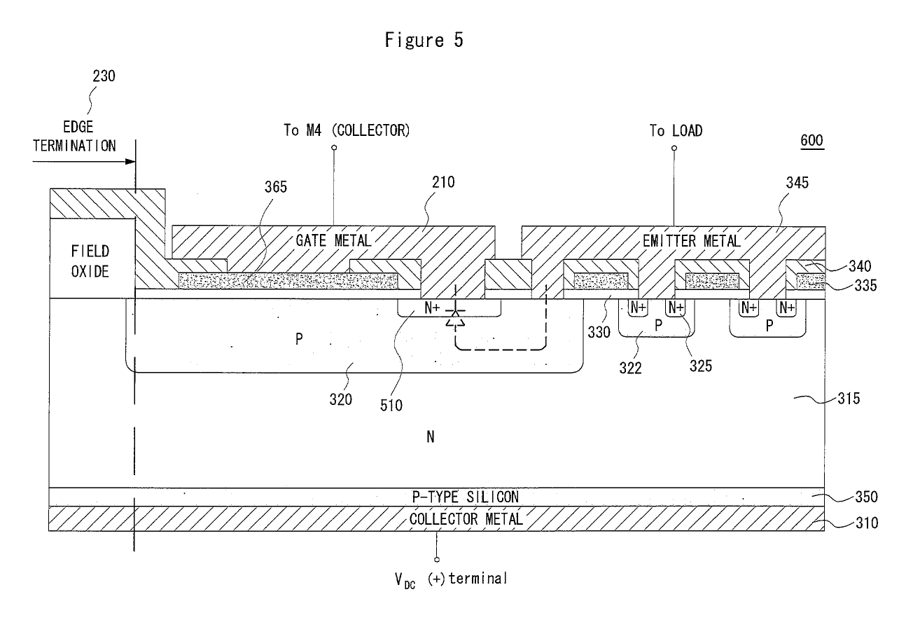

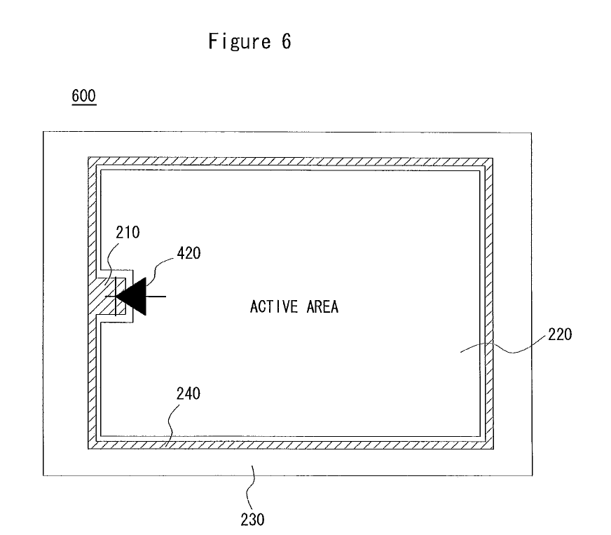

FIG. 5 is a sectional view taken along line a-b of FIG. 2 according to an embodiment of the invention. FIG. 6 is a conceptual plan view illustrating a semiconductor device according to an embodiment of the invention.

Referring to FIG. 5 which is a sectional view taken along line a-b of FIG. 2, in the semiconductor switching device 600, plural P-type wells 320 and 322 are formed in an N-type semiconductor substrate 315 and N-type wells 325 are selectively formed in the P-type wells 322. The P-type wells 322 forms an active cell allowing a current to flow at the time of turning on the semiconductor switching device 600. A channel can be formed in the P-type well 322, allowing a current to flow by connecting the semiconductor substrate 315 to the N-type wells 325 when a gate voltage having a predetermined magnitude is applied to a gate metal electrode 210. An insulating interlayer 340 is formed to include a gate ploy electrode 335 therein and an emitter metal electrode 345 including the active cells is formed thereon. A collector region 350 is formed under the N-type semiconductor substrate 315 and a collector metal electrode 310 is formed under the collector region 350 by a bottom metal process. The collector region 350 is formed in a P type in case of the IGBT, and is formed in an N type as a drain region in case of the MOSFET.

An N-type well 510 for forming a PN-junction diode is formed in the P-type well 320 formed in the N-type semiconductor substrate 315. The gate oxide film 330 is formed on the P-type well 320 and the N-type well 510. A gate poly pad 365 is formed on the gate oxide film 330. The gate poly pad 365 is electrically connected to the gate pad electrode formed of metal. The gate poly pad 365 may not be formed as needed, and the thickness of the gate oxide film can be changed variously.

As shown in FIG. 5, the diode built in the semiconductor switching device 600 is a PN-junction diode, where an anode is formed of one or more P-type wells and the cathode is formed of one or more N-type wells formed in the anodes. That is, the semiconductor switching device 600 can be formed to have plural diodes built therein and each diode can be formed in one or more of a serial connection and a parallel connection between the emitter terminal and the gate terminal of the semiconductor switching device 600.

The P-type wells serving as the anodes are electrically connected to the emitter metal electrode 345 directly or indirectly. The N-type wells serving as the cathodes are electrically connected to the gate metal electrode 210 directly or indirectly. For example, the P-type wells are electrically connected to the emitter metal electrode 345 via a contact hole and the N-type wells are electrically connected to the gate pad electrode 210 via a contact hole.

The layout of the semiconductor switching device 60 having the above-mentioned configuration is conceptually shown in FIG. 6. That is, the semiconductor switching device 600 includes the diode 420 arranged in a direction from the active area 220 to the gate pad electrode 210.

When the semiconductor switching device 600 shown in FIGS. 5 and 6 is the semiconductor switching device M1 shown in FIG. 4 and including the diode 420, the collector metal electrode 310 is connected to a + terminal of an input voltage and the emitter metal electrode 345 supplying the current to the load 120 in a normal operating state is electrically connected to the output node 110. The diode 420 formed by PN junction is disposed between the emitter metal electrode 345 and the gate metal electrode 210 and the gate metal electrode 210 is connected to the collector metal electrode of the lower semiconductor switching device M4.

Accordingly, in a normal state, the upper semiconductor switching device M1 supplies a current to the load 120 via the emitter metal electrode 345. However, in an abnormal state, when the upper semiconductor switching device M1 and the lower semiconductor switching device M4 are both turned on and a shoot-through phenomenon may occur, the current flowing out from the emitter metal electrode 345 flows to the gate metal electrode 210 via the diode 420. In this case, a voltage drop is caused by the diode 420 and the gate potential is lower than the emitter potential. Accordingly, the gate potential of the upper semiconductor switching device M1 is less than a threshold voltage and thus the upper semiconductor switching device M1 is forcibly turned off. Since the upper semiconductor switching device M1 is turned off it is possible to prevent the deterioration and/or destruction of the upper semiconductor device M1 and thus to prevent the shoot-through phenomenon from occurring.

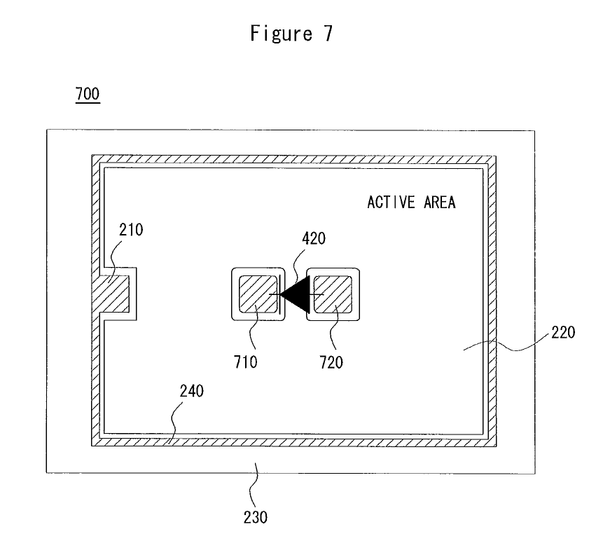

FIG. 7 is a plan view illustrating a semiconductor device according to another embodiment of the invention.

The anode and the cathode of a diode built in a semiconductor device 700 may include a metal electrode allowing the wire bonding for electrical connection between the emitter metal electrode 345 and the gate metal electrode 210.

Referring to FIG. 7, the semiconductor device 700 the gate metal electrode 210 and the emitter electrode 345 (see FIG. 5), which are electrically isolated from each other, on the top surface. A cathode pad 710 and an anode pad 720 for electrically connecting the diode 420 built in a part of the active area 220 to the gate metal electrode 210 and the emitter metal electrode 345 of the semiconductor device 700 may be further disposed on the top surface. The sectional structure of the semiconductor device 700 can be easily understood with reference to the sectional view shown in FIG. 5 and thus description thereof will not be repeated.

The P-type wells and the N-type wells formed under than active area 220 so as to serve as a PN-junction diode are formed as described above so that the N-type wells are included in the P-type wells. The P-type wells are electrically connected to the anode pad 720 and the N-type wells are electrically connected to the cathode pad 710.

The cathode pad 710 is electrically connected to the gate metal electrode 210 of the semiconductor device 700 using a metal wire and the anode pad 720 is electrically connected to the emitter metal electrode 345 of the semiconductor device 700 using a metal wire. Here, when the semiconductor device is a MOSFET, the emitter corresponds to the source.

While the invention is described with reference to the embodiments, it will be understood by those skilled in the art that the invention is modified and changed in various forms without departing from the spirit and scope of the invention described in the appended claims.

What is claimed is:

1. A MOS-gate power semiconductor device comprising:
one or more P-type wells formed under one or more of a gate metal electrode and a gate bus line and electrically connected to an emitter metal electrode; and
one or more N-type wells formed in the P-type well and electrically connected to one or more of the gate metal electrode and the gate bus line.

2. The MOS-gate power semiconductor device according to claim 1, wherein the P-type wells serve as an anode of a diode and the N-type wells serve as a cathode of the diode.

3. The MOS-gate power semiconductor device according to claim 1, wherein the P-type wells and the N-type wells are formed by performing an ion implantation process and a diffusion process on a semiconductor substrate.

4. The MOS-gate power semiconductor device according to claim 1, wherein a plurality of diodes formed using P-type ions of the P-type wells and N-type ions of the N-type wells are arranged in one or more of a serial connection and a parallel connection between a gate terminal and an emitter terminal.

5. The MOS-gate power semiconductor device according to claim 1, wherein the MOS-gate power semiconductor device serves as one or more of an insulated gate bipolar transistor (IGBT) and a metal-oxide semiconductor field effect transistor (MOSFET).

6. A MOS-gate power semiconductor device comprising:
one or more P-type wells formed in a semiconductor substrate so as to electrically be connected to an anode metal pad exposed from a surface of the MOS-gate power semiconductor device; and
one or more N-type wells formed in the semiconductor substrate so as to electrically be connected to a cathode metal pad exposed from the surface.

7. The MOS-gate power semiconductor device according to claim 6, wherein the anode metal pad is electrically connected to an emitter metal electrode and the cathode metal pad is electrically connected to a gate metal electrode.

8. The MOS-gate power semiconductor device according to claim 6, wherein the P-type wells and the N-type wells are formed by performing an ion implantation process and a diffusion process on the semiconductor substrate.

9. The MOS-gate power semiconductor device according to claim 8, wherein the N-type wells are formed in the P-type wells so as to serve as a PN-junction diode.

10. The MOS-gate power semiconductor device according to claim 8, wherein the P-type wells and the N-type wells are formed in an area other than an edge termination area.

11. The MOS-gate power semiconductor device according to claim 6, wherein the anode metal pad and the cathode metal pad are formed in an active area so as to be exposed from the active area.

12. The MOS-gate power semiconductor device according to claim 11, wherein a plurality of diodes are arranged in one or more of a serial connection and a parallel connection between a gate metal terminal and an emitter metal terminal by wiring the anode metal pad and the cathode metal pad.

13. The MOS-gate power semiconductor device according to claim 6, wherein the MOS-gate power semiconductor device serves as one or more of an insulated gate bipolar transistor (IGBT) and a metal-oxide semiconductor field effect transistor (MOSFET).
